(19) United States
(12) Patent Application Publication
(10) Pub. No.: US 2025/0264541 A1
(43) Pub. Date: Aug. 21, 2025

(54) BATTERY INFORMATION GENERATING APPARATUS AND METHOD

(71) Applicant: LG ENERGY SOLUTION, LTD., Seoul (KR)

(72) Inventors: A-Ming CHA, Daejeon (KR); Kyung-Eun SUN, Daejeon (KR); Yoon-Jung BAE, Daejeon (KR)

(21) Appl. No.: 19/054,509

(22) Filed: Feb. 14, 2025

(30) Foreign Application Priority Data
Feb. 16, 2024 (KR) 10-2024-0022912

(51) Int. Cl. G01R 31/389; G01R 31/3835

(52) U.S. Cl. CPC G01R 31/389; G01R 31/3835

(57) ABSTRACT

A battery information generating method according to an embodiment of the present disclosure includes obtaining a differential profile representing a corresponding relationship between a voltage and a differential capacity of a battery; detecting a peak in the differential profile; comparing a peak voltage corresponding to the peak with a preset reference voltage; determining a measurement resistance of the battery by determining a resistance during discharging of the battery for a predetermined time from a discharge start point; and determining a diagnostic resistance of the battery based on the measurement resistance according to a comparison result of comparing the peak voltage corresponding to the peak with the present reference voltage.

### CROSS-REFERENCE TO RELATED APPLICATIONS

This application is based on and claims priority from Korean Patent Application No. 10-2024-0022912, filed on Feb. 16, 2024, with the Korean Intellectual Property Office, the disclosure of which is hereby incorporated herein in its entirety by reference.

### TECHNICAL FIELD

The present disclosure relates to a battery information generating apparatus and method, and more specifically, to a battery information generating apparatus and method that generates battery information that more accurately reflects the state of a battery.

### BACKGROUND

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Examples of batteries that are commercially available at present include nickel-cadmium batteries, nickel hydrogen batteries, nickel-zinc batteries, lithium batteries and the like. Among them, the lithium batteries are in the limelight since they have almost no memory effect compared to nickel-based batteries and also have very low self-charging rate and high energy density.

Although much research is being conducted on these batteries in terms of high capacity and high density, improving lifespan and safety is also important. In order to improve battery safety, technology that accurately diagnoses the current state of the battery is required.

Based on the fact that the internal resistance of a battery increases as the battery deteriorates, the resistance measured at the beginning of discharge after the end of charging of the battery was used as a degradation index in the past. That is, the resistance calculated based on the amount of voltage change for a predetermined time from the discharge start point after the end of charging was used as a degradation index.

However, as the battery deteriorates, the overvoltage due to polarization increases, so the voltage when measuring resistance actually decreases. And, due to the decrease in voltage, the measured resistance is also smaller than the actual value.

In the case of a battery that shows a minimal change in resistance according to voltage in the high-voltage section, the decrease in resistance due to the decrease in voltage is minimal, so there is no great need to correct the measured resistance.

However, in the case of a battery that shows a large change in resistance according to voltage in the high-voltage section, it is necessary to consider the decrease in resistance according to the decrease in voltage. That is, in order to more accurately calculate the resistance as a degradation index, it is necessary to correct the measured resistance by considering the decrease in voltage.

Therefore, a technology is needed that may determine whether the measured resistance corresponds to a battery that needs to be corrected, and if the need for correction is recognized, a technology is needed that may correct the measured resistance by taking into account the voltage decrease.

### SUMMARY

Embodiments of the present disclosure are designed to at least partly address, and even solve, the problems of the related art, and therefore embodiments of the present disclosure are directed to providing a battery information generating method and device for determining whether or not a battery requires correction of a measured resistance.

In addition, embodiments of the present disclosure are directed to providing a battery information generating method and device that corrects the measured resistance by considering the decrease in voltage when the necessity of correction is recognized.

These and other objects and advantages of embodiments of the present disclosure may be understood from the following detailed description and will become more fully apparent from the exemplary embodiments of the present disclosure. Also, it will be easily understood that the objects and advantages of embodiments of the present disclosure may be realized by the means shown in the appended claims and combinations thereof.

A battery information generating method according to one aspect of the present disclosure may comprise obtaining a differential profile representing a corresponding relationship between a voltage and a differential capacity of a battery; detecting a peak in the differential profile; comparing a peak voltage corresponding to the peak with a preset reference voltage; determining a measurement resistance of the battery by determining a resistance during discharging of the battery for a predetermined time from a discharge start point; and determining a diagnostic resistance of the battery based on the measurement resistance according to a comparison result of comparing the peak voltage corresponding to the peak with the preset reference voltage.

Determining the diagnostic resistance may include determining the measurement resistance as the diagnostic resistance when the peak voltage is less than the reference voltage. Determining the diagnostic resistance may further include determining the voltage of the discharge start point as a measurement voltage when the peak voltage is greater than or equal to the reference voltage.

Determining the diagnostic resistance may include correcting the measurement resistance based on the measurement voltage, the peak voltage and a preset resistance profile; and determining the corrected measurement resistance as the diagnostic resistance.

The resistance profile may be a profile that is preset to correspond to the battery and represents a corresponding relationship between the voltage and a resistance.

Correcting the measurement resistance may include calculating a first value based on the measurement voltage and a target voltage; calculating a second value based on the target voltage and the resistance profile; calculating a third value based on the first value and the second value; and calculating the corrected measurement resistance based on the third value and the measurement resistance.

The target voltage may be determined as corresponding to a voltage that is greater than or equal to the reference voltage among the peak voltages.

The first value may correspond to a difference between the measurement voltage and the target voltage.

The second value may correspond to a rate of change of the resistance for the voltage in a target voltage section of the resistance profile.

The target voltage section may correspond to a voltage section that is greater than or equal to the target voltage.

The third value may be a value that is obtained by multiplying the first value by the second value.

The corrected measurement resistance may be a value that is obtained by adding the third value to the measurement resistance.

A battery information generating apparatus according to another aspect of the present disclosure may comprise a profile obtaining unit configured to obtain a differential profile representing a corresponding relationship between a voltage and a differential capacity of a battery; a voltage comparing unit configured to detect a peak in the differential profile and compare a peak voltage corresponding to the peak with a preset reference voltage; a measurement value determining unit configured to determine a measurement resistance of the battery by determining a resistance during discharging of the battery for a predetermined time from a discharge start point; and a diagnostic resistance determining unit of configured to determine a diagnostic resistance of the battery based on the measurement resistance according to a comparison result of comparing the peak voltage corresponding to the peak with the preset reference voltage.

The diagnostic resistance determining unit may be configured to determine the measurement resistance as the diagnostic resistance when the peak voltage is less than the reference voltage.

The measurement value determining unit may be configured to determine the voltage of the discharge start point as a measurement voltage when the peak voltage is greater than or equal to the reference voltage.

The diagnostic resistance determining unit may be configured to correct the measurement resistance based on the measurement voltage, the peak voltage and a preset resistance profile, and determine the corrected measurement resistance as the diagnostic resistance.

The resistance profile may be a profile that is preset to correspond to the battery and represents a corresponding relationship between the voltage and a resistance.

The diagnostic resistance determining unit may be configured to calculate a first value based on the measurement voltage and a target voltage, calculate a second value based on the target voltage and the resistance profile; calculate a third value based on the first value and the second value, and calculate the corrected measurement resistance based on the third value and the measurement resistance.

A battery pack according to still another aspect of the present disclosure may comprise the battery information generating apparatus according to another aspect of the present disclosure.

According to one aspect of the present disclosure, diagnostic resistance may be more accurately determined by determining whether or not the measurement resistance needs to be corrected through voltage comparison based on the differential profile.

According to one aspect of the present disclosure, when determining diagnostic resistance as a degradation index, the diagnostic resistance may be determined more accurately by considering the change in voltage during resistance measurement.

According to one aspect of the present disclosure, the diagnostic resistance may be determined more accurately by setting the reference voltage considering the state of the battery.

The effects of the present disclosure are not limited to the effects mentioned above, and other effects not mentioned will be clearly understood by those skilled in the art from the description of the claims.

### DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a flow chart of a battery information generating method according to an embodiment of the present disclosure.

FIG. 2 is a drawing schematically illustrating a battery information generating apparatus according to an embodiment of the present disclosure.

FIG. 3 is a flow chart more specifically illustrating a voltage comparing step, a measurement resistance determining step, and a diagnostic resistance determining step of the battery information generating method according to an embodiment of the present disclosure.

FIG. 4 is a flow chart illustrating more specifically the measurement resistance correcting step of the battery information generating method according to an embodiment of the present disclosure.

FIG. 5 is a drawing schematically illustrating a differential profile according to an embodiment of the present disclosure.

FIG. 6 is a drawing schematically illustrating a resistance profile according to an embodiment of the present disclosure.

FIG. 7 is a drawing illustrating an exemplary configuration of a battery pack according to another embodiment of the present disclosure.

### DETAILED DESCRIPTION

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

The terms including the ordinal number such as “first”, “second” and the like, may be used to distinguish one element from another among various elements, but not intended to limit the elements by the terms.

Throughout the specification, when a portion is referred to as “comprising” or “including” any element, it means that the portion may include other elements further, without excluding other elements, unless specifically stated otherwise.

In addition, throughout the specification, when a portion is referred to as being “connected” to another portion, it is not limited to the case that they are “directly connected”, but it also includes the case where they are “indirectly connected” with another element being interposed between them.

Hereinafter, preferred embodiments of the present disclosure will be described in detail with reference to the accompanying drawings.

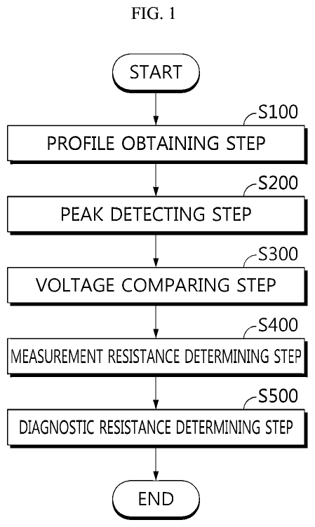

FIG. 1 is a flow chart of a battery information generating method according to an embodiment of the present disclosure.

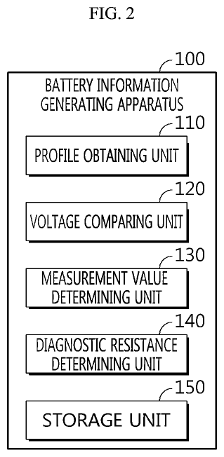

FIG. 2 is a drawing schematically illustrating a battery information generating apparatus 100 according to an embodiment of the present disclosure.

Referring to FIG. 1, the battery information generating method may include a profile obtaining step (S100), a peak detecting step (S200), a voltage comparing step (S300), a measurement resistance determining step (S400), and a diagnostic resistance determining step (S500). Preferably, each step of the battery information generating method may be performed by the battery information generating apparatus 100.

Referring to FIG. 2, the battery information generating apparatus 100 may include a profile obtaining unit 110, a voltage comparing unit 120, a measurement value determining unit 130, and a diagnostic resistance determining unit 140.

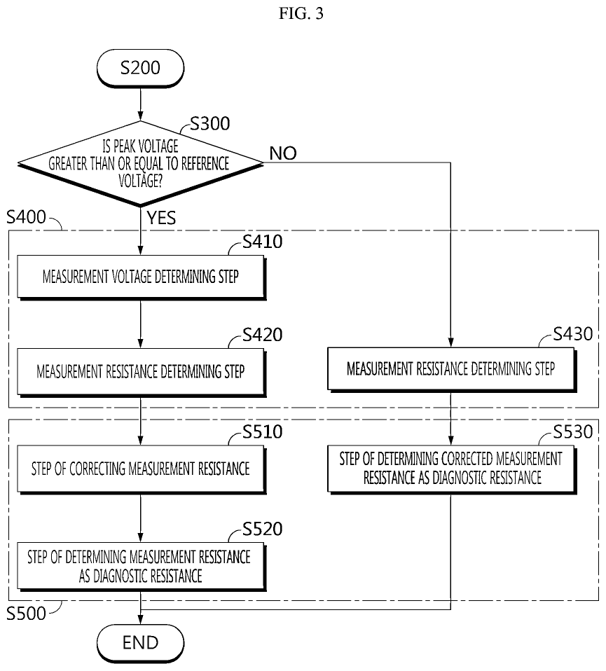

FIG. 3 is a flow chart more specifically illustrating a voltage comparing step (S300), a measurement resistance determining step (S400), and a diagnostic resistance determining step (S500) of the battery information generating method according to an embodiment of the present disclosure.

Here, the battery refers to an independent cell that has a negative terminal and a positive terminal and is physically separable. As an example, a lithium-ion battery or a lithium polymer battery may be considered as a battery. In addition, the type of batteries may be a cylindrical type, a prismatic type or a pouch type. Additionally, the battery may mean a battery bank, a battery module or a battery pack in which a plurality of cells are connected in series and/or parallel. Below, for convenience of explanation, the battery is explained as meaning one independent cell.

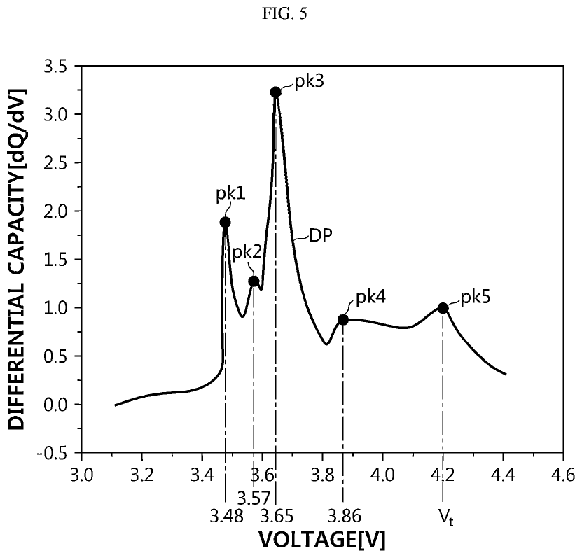

FIG. 5 is a drawing schematically illustrating a differential profile DP according to an embodiment of the present disclosure.

In the embodiment of FIG. 5, the horizontal axis (X-axis) represents voltage (V), and the vertical axis (Y-axis) represents differential capacity (dQ/dV).

According to certain embodiments, the profile obtaining step (S100) is a step of obtaining a differential profile DP representing a corresponding relationship between the voltage and differential capacity of the battery, and may be performed by the profile obtaining unit 110.

Here, the differential capacity represents the instantaneous rate of change of capacity with respect to voltage. That is, the differential capacity may be expressed as ‘dQ/dV’ as the value obtained by differentiating the capacity with respect to voltage.

The battery profile is a profile that represents the corresponding relationship between voltage (V) and capacity (Q) while the battery is being charged. Then, when the battery profile is differentiated with respect to voltage, a differential profile DP that represents the corresponding relationship between differential capacity and voltage may be generated. That is, the battery profile is obtained during the process of charging the battery, and the differential profile DP may be obtained from the battery profile.

For example, there is no special limitation on the C-rate in charging for generating a battery profile. However, preferably, the battery should be charged at a low rate in order to obtain a more accurate battery profile and differential profile DP. For example, the battery profile may be generated in the process of charging the battery at 0.05 C.

For example, the profile obtaining unit 110 may directly receive the differential profile DP of the battery from the outside. That is, the profile obtaining unit 110 may obtain the differential profile DP of the battery by being connected to the outside by wire and/or wirelessly and receiving the differential profile DP.

As another example, the profile obtaining unit 110 may receive battery information about the voltage and capacity of the battery. Then, the profile obtaining unit 110 may directly generate a differential profile DP based on the received battery information.

As still another example, the profile obtaining unit 110 may measure the voltage and current of the battery. For example, the profile obtaining unit 110 may be connected to the positive electrode terminal and the negative electrode terminal of the battery to measure the voltage of the battery. In addition, the profile obtaining unit 110 may measure the charge/discharge current of the battery and calculate the capacity of the battery based on the measured current. In addition, the profile obtaining unit 110 may generate a differential profile DP based on the voltage and capacity of the battery.

According to certain embodiments, the peak detecting step (S200) is a step of detecting a peak in the differential profile DP, and may be performed by the voltage comparing unit 120.

Here, the peak may mean the point where the slope (instantaneous rate of change) of the profile changes from a positive (+) value to a negative (−) value. That is, the slope on the low voltage side centered on the peak is positive, and the slope on the high voltage side is negative. In other words, the maximum point of the differential profile may be determined as the peak.

Referring to FIG. 5, multiple peaks (pk1, pk2, pk3, pk4, pk5) may be detected in the differential profile DP.

The voltage comparing unit 120 may compare the peak voltage corresponding to the peak with a preset reference voltage.

Here, the reference voltage may be preset to reflect the state of the battery. Alternatively, the reference voltage may be preset to a predetermined voltage value (e.g., 4 V).

In the following, the description is made assuming that the reference voltage is preset to 4 V. In addition, for convenience of explanation, a specific example of setting the reference voltage by reflecting the state of the battery is described later.

For example, the voltage comparing unit 120 may compare the magnitude of the peak voltage and the reference voltage. Specifically, the voltage comparing unit 120 may determine whether the peak voltage is equal to or greater than a reference voltage. Here, the peak voltage being equal to or greater than the reference voltage means that the voltage corresponding to at least one peak among the plurality of peaks is equal to or greater than the reference voltage. In other words, the voltage comparing unit 120 may determine whether the peak voltage is less than the reference voltage. Here, the peak voltage being less than the reference voltage means that the voltage corresponding to each of the plurality of peaks is all less than the reference voltage.

In the embodiment of FIG. 5, the peak voltage corresponding to the peak (pk1) is 3.48 V, the peak voltage corresponding to the peak (pk2) is 3.57 V, the peak voltage corresponding to the peak (pk3) is 3.65 V, the peak voltage corresponding to the peak (pk4) is 3.86 V, and the peak voltage corresponding to the peak (pk5) is 4.20 V. When comparing the magnitude of each peak voltage and the reference voltage, the peak voltage (3.48 V) corresponding to the peak (pk1), the peak voltage (3.57 V) corresponding to the peak (pk2), the peak voltage (3.65 V) corresponding to the peak (pk3), and the peak voltage (3.86 V) corresponding to the peak (pk4) are less than the reference voltage (4 V). In addition, the peak voltage (4.2 V) corresponding to the peak (pk5) is greater than or equal to the reference voltage (4 V). Since the voltage corresponding to at least one peak (pk5) among multiple peaks (pk1, pk2, pk3, pk4, pk5) is greater than or equal to the reference voltage, the voltage comparing unit 120 may determine that the peak voltage is greater than or equal to the reference voltage.

According to certain embodiments, the measurement resistance determining step (S400) is a step of determining the resistance for a predetermined time from a discharge start point as the measurement resistance by performing a discharge on the battery, and may be performed by the measurement value determining unit 130.

Specifically, the measurement value determining unit 130 may determine the resistance change amount for a predetermined time from the time point at which the next discharge cycle starts after the end of the charge cycle in which the differential profile DP is obtained, as the measurement resistance.

More specifically, the battery may be charged until the voltage (or SOC) reaches a preset charge termination voltage (or preset charge termination SOC). Then, the measurement value determining unit 130 may calculate the resistance of the battery based on the voltage change amount and the discharge current from the start point of the discharge cycle until a predetermined time elapses after the charge cycle is terminated.

For example, for the sake of further clarification, it is assumed that the discharge current is Id, the discharge start voltage is Vi, and the voltage after a predetermined time has elapsed after the discharge start is Vf. In this case, the measurement value determining unit 130 may calculate the measurement resistance by calculating the formula of “(Vi-Vf)=Id” using Ohm's law. In addition, the predetermined time here may be a preset time experimentally or theoretically. For example, the predetermined time may be preset to 0.1 second, 1 second, or 60 seconds.

According to certain embodiments, the diagnostic resistance determining step (S500) is a step of determining the diagnostic resistance of the battery based on the measurement resistance according to the comparison result of the voltage comparing step (S300), and may be performed by the diagnostic resistance determining unit 140. The diagnostic resistance determining step (S500) may include a measurement resistance correcting step (S510), a step of determining the corrected measurement resistance as the diagnostic resistance (S520), and a step of determining the measurement resistance as the diagnostic resistance (S530).

If the peak voltage is less than the reference voltage, the diagnostic resistance determining unit 140 may determine the measurement resistance as the diagnostic resistance without correction for the measurement resistance. Conversely, if the peak voltage is greater than or equal to the reference voltage, the diagnostic resistance determining unit 140 may correct the measurement resistance and determine the corrected measurement resistance as the diagnostic resistance.

Referring to FIG. 3, in step S300, it may be determined whether the peak voltage is greater than or equal to the reference voltage. If the result of step S300 is YES, step S410 may be performed. If the result of step S300 is NO, step S430 may be performed.

According to certain embodiments, step S410 is a step of determining the voltage of the discharge start point as the measurement voltage, and may be performed by the measurement value determining unit 130.

That is, the measurement resistance determining step (S400) may further include a measurement voltage determining step (S410) that determines the voltage of the discharge start point as the measurement voltage if the peak voltage is greater than or equal to the reference voltage.

Specifically, the measurement value determining unit 130 may determine the voltage at the time point when the next discharge cycle starts after the charge cycle in which the differential profile DP is obtained is terminated, as the measurement voltage.

More specifically, the battery may be charged until the voltage (or SOC) reaches a preset charge termination voltage (or preset charge termination SOC). Then, the measurement value determining unit 130 may determine the voltage at the start point of the discharge cycle as the measurement voltage after the charge cycle is terminated.

According to certain embodiments, step S420 is a step for determining measurement resistance, and may be performed by the measurement value determining unit 130. Meanwhile, steps S420 and S430 may be the same steps for determining measurement resistance, but are illustrated separately in FIG. 3 for convenience of explanation.

After the measurement resistance determining step (S420), step S510 may be performed. According to certain embodiments, step S510 is a step for correcting the measurement resistance, and may be performed by the diagnostic resistance determining unit 140.

Specifically, the diagnostic resistance determining unit 140 may correct the measurement resistance based on the measurement voltage, peak voltage, and preset resistance profile.

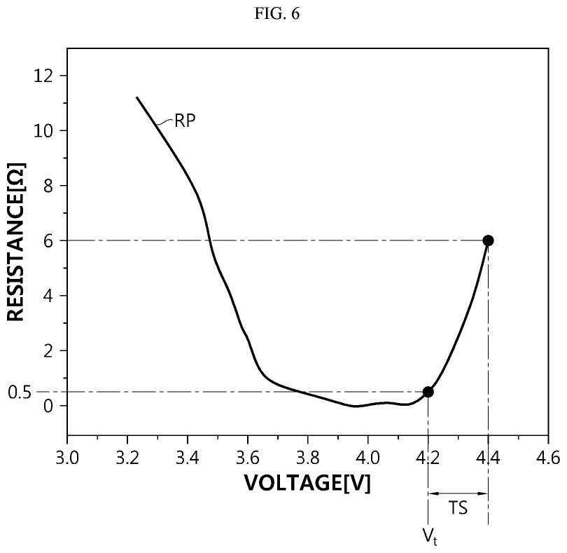

FIG. 6 is a drawing schematically illustrating a resistance profile RP according to an embodiment of the present disclosure.

In the embodiment of FIG. 6, the horizontal axis (X-axis) represents voltage (V), and the vertical axis (Y-axis) represents resistance (22).

The resistance profile RP may be a profile that is preset to correspond to the battery and represents the corresponding relationship between voltage and resistance.

Here, voltage may mean open circuit voltage (OCV). Resistance may be calculated based on the voltage change amount when a pulse signal is applied to the battery. For example, it may mean the resistance calculated based on the voltage change amount recorded for 0.1 second when a pulse signal (e.g. 0.5C C-rate) is given and Ohm's law.

For example, the resistance profile RP may be preset to represent the corresponding relationship between the voltage and resistance measured during the charging process of a preset criterion battery. The criterion battery may mean a battery designed with the same specifications as the battery subject to the present disclosure.

As another example, the resistance profile RP may be preset to represent the corresponding relationship between the voltage and resistance measured during the charging process when the battery is in the BoL (Beginning of Life) state.

For convenience of explanation, a specific example in which the diagnostic resistance determining unit 140 corrects the measurement resistance is described below.

According to certain embodiments, step S520 is a step of determining the corrected measurement resistance as the diagnostic resistance, which may be performed by the diagnostic resistance determining unit 140.

After the measurement resistance determining step (S430), step S530 may be performed. According to certain embodiments, step S530 is a step of determining the measurement resistance as the diagnostic resistance, and may be performed by the diagnostic resistance determining unit 140.

An embodiment of the battery information generating method according to the present disclosure may more accurately determine diagnostic resistance by determining whether or not the measurement resistance needs to be corrected through voltage comparison based on a differential profile. That is, the diagnostic resistance may be determined differently depending on the type of battery (e.g., high nickel battery, low nickel battery, etc.).

Below, a specific embodiment in which the diagnostic resistance determining unit 140 corrects the measurement resistance in step S510 is described in more detail.

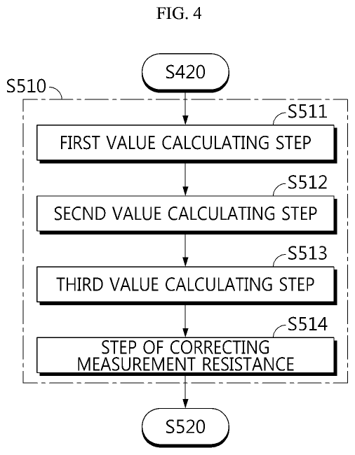

FIG. 4 is a flow chart illustrating more specifically the measurement resistance correcting step (S510) of the battery information generating method according to an embodiment of the present disclosure.

Referring to FIG. 4, step S510 may include a first value calculating step (S511), a second value calculating step (S512), a third value calculating step (S513), and a step of correcting the measurement resistance (S514).

According to certain embodiments, step S511 is a step of calculating a first value based on the measurement voltage and the target voltage, and may be performed by the diagnostic resistance determining unit 140 after step S420.

Here, the target voltage may be determined as a peak voltage that is greater than or equal to the reference voltage. Specifically, since step S510 is performed when the peak voltage is greater than or equal to the reference voltage, if there is one peak detected in the peak detecting step (S200), the voltage corresponding to that peak may be determined as the target voltage. If there are multiple peaks detected in the peak detecting step (S200), the voltage of a peak among the multiple peaks whose corresponding voltage is greater than or equal to the reference voltage may be determined as the target voltage.

Here, it is assumed that there are multiple target peaks among the multiple peaks whose corresponding voltage is greater than or equal to the reference voltage. In this case, preferably, the voltage corresponding to the largest differential capacity among the differential capacities of the multiple target peaks may be determined as the target voltage.

Specifically, the diagnostic resistance determining unit 140 may calculate the difference between the measurement voltage and the target voltage as the first value.

In the embodiment of FIG. 5, the voltage (4.2 V) of a peak (pk5) among a plurality of peaks (pk1, pk2, pk3, pk4, pk5) whose corresponding voltage is greater than or equal to the reference voltage (4 V) may be determined as the target voltage (Vₜ). Assuming that the measurement voltage is Vₘ, the first value may be expressed as (Vₘ-Vₜ), which is the difference between the measurement voltage (Vₘ) and the target voltage (Vₜ).

According to certain embodiments, step S512 is a step of calculating a second value based on the target voltage and the resistance profile RP, and may be performed by the diagnostic resistance determining unit 140.

Specifically, the diagnostic resistance determining unit 140 may determine the rate of change of resistance with respect to voltage in the target voltage section (TS) of the resistance profile RP as a second value.

The target voltage section (TS) may be a voltage section greater than or equal to the target voltage (Vₜ). That is, the lower limit of the target voltage section (TS) may be set to the target voltage (Vₜ), and the upper limit may be set to the upper limit of the resistance profile.

In the embodiment of FIG. 6, the target voltage (Vₜ) is 4.2 V and the upper limit of the resistance profile RP is 4.4 V, so the target voltage section (TS) may be set to a voltage section of 4.2 V to 4.4 V.

For example, the second value may be set to the slope of a function obtained by linearly approximating a function representing the corresponding relationship between the voltage included in the target voltage section (TS) and the resistance corresponding to the voltage. That is, the slope when the resistance is expressed as a linear function of the voltage may be set to the second value.

As another example, the second value may be set to the average rate of change of resistance with respect to voltage in the target voltage section (TS).

In the embodiment of FIG. 6, the average rate of change (i.e., (6-0.5)=(4.4-4.2)=27.5) based on the lower limit voltage (or starting voltage, e.g., 4.2 V), the upper limit voltage (or ending voltage, e.g., 4.4 V), the resistance corresponding to the lower limit voltage (e.g., 0.5Ω), and the resistance corresponding to the upper limit voltage (e.g., 6Ω) of the target voltage section (TS) may be set as the second value.

As another example, the second value may be set to the target voltage (Vₜ) of the target voltage section (TS) and the instantaneous rate of change in resistance corresponding to the target voltage (Vₜ).

In the embodiment of FIG. 6, the instantaneous rate of change in the target voltage (Vₜ, e.g., 4.2 V) and the resistance corresponding to the target voltage (e.g., 0.5Ω) may be set as the second value.

Preferably, the second value may be set to the slope of a linear approximation function for the target voltage section (TS).

Step S513 is a step of calculating a third value based on the first value and the second value, and may be performed by the diagnostic resistance determining unit 140.

Specifically, the diagnostic resistance determining unit 140 may calculate a third value by multiplying the first value and the second value. Here, the third value is a constant for correcting the measurement resistance.

Step S514 is a step of calculating a corrected measurement resistance based on the third value and the measurement resistance, and may be performed by the diagnostic resistance determining unit 140.

Specifically, the diagnostic resistance determining unit 140 may calculate the corrected measurement resistance by adding the measurement resistance and the third value.

For example, the corrected measurement resistance may be calculated using Formula 1 below.

$${R}_{calib} = {R}_{m} + ( {V}_{m} - {V}_{t} ) \times a \qquad [ Formula 1 ]$$

Here, R_{calib} represents the corrected measurement resistance, and Rₘ represents the measurement resistance. Vₘ represents the measurement voltage, Vₜ represents the target voltage, and a represents the rate of change of resistance with respect to voltage in the target voltage section.

Based on the fact that the internal resistance of the battery increases as the battery deteriorates, the measurement resistance was used as a degradation index in the past. That is, the resistance calculated based on the voltage change amount for a predetermined time from the discharge start point after the end of charging was used as a degradation index.

However, as the battery deteriorates, the overvoltage due to polarization (e.g., ohmic polarization, activation polarization, concentration polarization, etc.) increases, so the measurement voltage actually gradually decreases. And, due to the decrease in measurement voltage, the measured resistance is also smaller than the actual value. Therefore, in order to more accurately calculate the resistance as a degradation index, it is necessary to correct the measured resistance by considering the decrease in measurement voltage.

The battery information generating method according to an embodiment of the present disclosure may more accurately determine diagnostic resistance by considering the change in voltage during resistance measurement when determining the diagnostic resistance as a degradation index. That is, the diagnostic resistance may be more accurately determined by considering the decrease in resistance due to a decrease in measurement voltage caused by battery degradation.

Below, a specific example of setting the reference voltage by reflecting the state of the battery is described.

For example, the reference voltage may be set by considering the negative electrode flat section of the battery. Specifically, the reference voltage may be set to a voltage corresponding to the lower limit capacity of the negative electrode flat section in the battery profile. That is, the reference voltage and the lower limit capacity of the negative electrode flat section in the battery profile may exhibit a corresponding relationship.

In general, it is known that in the high capacity section, the positive electrode takes the lead in the reaction, and the negative electrode participates relatively less in the reaction. Due to the different reaction participation of the positive and negative electrodes, the capacity section where the rate of change in voltage with respect to capacity is insignificant may be called the negative electrode flat section.

The negative electrode flat section may mean a capacity section in which the voltage change of the negative electrode is minimal due to an increase in the capacity of the negative electrode. In other words, a capacity section in which the voltage change for the capacity is below a certain level may be preset as a negative electrode flat section.

In one embodiment, the negative electrode flat section may be set as a capacity section in which the rate of change of voltage with respect to capacity in the criterion negative electrode profile is less than or equal to a preset criterion ratio.

Here, the criterion negative electrode profile may be a profile representing a corresponding relationship between the capacity and voltage of a preset criterion negative electrode to correspond to the negative electrode of a battery. For example, the criterion negative electrode may be a negative electrode coin half cell or a negative electrode of a 3-electrode cell.

In another embodiment, the negative electrode flat section may be set to a capacity section greater than or equal to the capacity of the reference peak included in the reference differential profile. That is, the capacity of the reference peak may be set as the lower limit of the negative electrode flat section.

The reference peak may be set as a peak located in a higher capacity section than the minimum point of the corresponding differential voltage in the reference differential profile. That is, the capacity of the reference peak may be greater than or equal to the capacity corresponding to the lowest differential voltage in the reference differential profile.

The reference differential profile may be a profile that represents the corresponding relationship between the capacity and differential voltage of the battery.

Here, the differential voltage represents the instantaneous rate of change of voltage with respect to the capacity. That is, the differential voltage is a value obtained by differentiating voltage with respect to the capacity and may be expressed as ‘dV/dQ’.

The reference differential profile may be obtained by differentiating the battery profile, which is a profile representing the corresponding relationship between the voltage (V) and the capacity (Q) while the battery is being charged, with respect to the capacity. That is, the battery profile is obtained during the process of charging the battery, and the reference differential profile may be obtained from the battery profile.

The profile obtaining unit 110 may be configured to obtain a reference differential profile. For example, the profile obtaining unit 110 may directly receive a reference differential profile of the battery from the outside. As another example, the profile obtaining unit 110 may receive battery information about voltage and capacity of the battery. Then, the profile obtaining unit 110 may directly generate a reference differential profile based on the received battery information. As still another example, the profile obtaining unit 110 may measure voltage and current of the battery and calculate capacity. Then, the profile obtaining unit 110 may generate a reference differential profile based on the voltage and capacity of the battery.

In another embodiment, the reference peak may be set to a peak located in a predetermined capacity section in the reference differential profile.

The battery information generating method according to an embodiment of the present disclosure sets a reference voltage by considering the state of the battery, so that the diagnostic resistance may be determined more accurately.

Meanwhile, the profile obtaining unit 110, the voltage comparing unit 120, the measurement value determining unit 130 and the diagnostic resistance determining unit 140 included in the battery information generating apparatus 100 may optionally include processors, application-specific integrated circuits (ASICs), other chipsets, logic circuits, registers, communication modems, data processing devices, etc. known in the art to execute various control logics performed in the present disclosure. Also, when the control logic is implemented as software, the profile obtaining unit 110, the voltage comparing unit 120, the measurement value determining unit 130 and the diagnostic resistance determining unit 140 may be implemented as a set of program modules. At this time, the program module may be stored in the memory and executed by the profile obtaining unit 110, the voltage comparing unit 120, the measurement value determining unit 130 and the diagnostic resistance determining unit 140. The memory may be inside or outside the profile obtaining unit 110, the voltage comparing unit 120, the measurement value determining unit 130 and the diagnostic resistance determining unit 140 and may be connected to the profile obtaining unit 110, the voltage comparing unit 120, the measurement value determining unit 130 and the diagnostic resistance determining unit 140 by various well-known means.

In addition, the battery information generating apparatus 100 may further include a storage unit 150. The storage unit 150 may store data necessary for operation and function of each component of the battery information generating apparatus 100, data generated in the process of performing the operation or function, or the like. The storage unit 150 is not particularly limited in its kind as long as it is a known information storage means that can record, erase, update and read data. As an example, the information storage means may include RAM, flash memory, ROM, EEPROM, registers, and the like. In addition, the storage unit 150 may store program codes in which processes executable by the profile obtaining unit 110, the voltage comparing unit 120, the measurement value determining unit 130 and the diagnostic resistance determining unit 140 are defined.

Specifically, the storage unit 150 may store information necessary for the profile obtaining unit 110, the voltage comparing unit 120, the measurement value determining unit 130, and the diagnostic resistance determining unit 140 to generate information of the battery. For example, the storage unit 150 may store a reference voltage, a resistance profile RP, a reference negative electrode profile, and a criterion ratio. In addition, the profile obtaining unit 110, the voltage comparing unit 120, the measurement value determining unit 130, and the diagnostic resistance determining unit 140 may access the storage unit 150 to obtain information necessary for diagnosing the state of the battery.

The battery information generating apparatus 100 according to embodiments of the present disclosure may be applied to a battery management system (BMS). That is, the BMS according to embodiments of the present disclosure may include the battery information generating apparatus 100 according to embodiments described above. In this configuration, at least some of components of the battery information generating apparatus 100 may be implemented by supplementing or adding functions of the components included in a conventional BMS. For example, the profile obtaining unit 110, the voltage comparing unit 120, the measurement value determining unit 130, the diagnostic resistance determining unit 140 and the storage unit 150 of the battery information generating apparatus 100 may be implemented as components of the BMS.

Additionally, the battery information generating apparatus 100 according to embodiments of the present disclosure may be provided in the battery pack. That is, the battery pack according to embodiments the present disclosure may include embodiments of the above-described battery information generating apparatus 100 and at least one battery cell. Additionally, the battery pack may further include electrical components (relays, fuses, etc.) and a case.

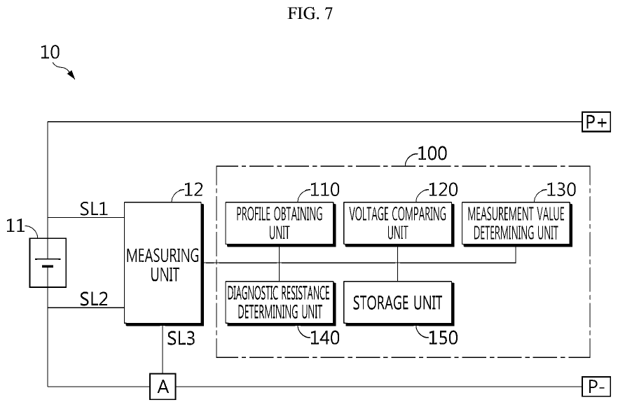

FIG. 7 is a drawing showing an exemplary configuration of a battery pack 10 according to still another embodiment of the present disclosure.

The positive electrode terminal of the battery 11 may be connected to the positive electrode terminal P+ of the battery pack 10, and the negative electrode terminal of the battery 11 may be connected to the negative electrode terminal P− of the battery pack 10.

The measuring unit 12 may be connected to the first sensing line SL1, the second sensing line SL2, and the third sensing line SL3. Specifically, the measuring unit 12 may be connected to the positive electrode terminal of the battery 11 through the first sensing line SL1 and connected to the negative electrode terminal of the battery 11 through the second sensing line SL2. The measuring unit 12 may measure the voltage of the battery 11 based on the voltage measured at each of the first sensing line SL1 and the second sensing line SL2.

Also, the measuring unit 12 may be connected to the current measuring unit A through the third sensing line SL3. For example, the current measuring unit A may be an ammeter or a shunt resistor capable of measuring the charging current and the discharging current of the battery 11. The measuring unit 12 may measure the charging current of the battery 11 through the third sensing line SL3 to calculate the charge amount. In addition, the measuring unit 12 may measure the discharging current of the battery 11 through the third sensing line SL3 to calculate the discharge amount.

An external device (not shown) may have one end connected to the positive electrode terminal P+ of the battery pack 10 and the other end connected to the negative electrode terminal P− of the battery pack 10. Therefore, the positive electrode terminal of the battery 11, the positive electrode terminal P+ of the battery pack 10, the external device, the negative electrode terminal P− of the battery pack 10, and the negative electrode terminal of the battery 11 may be electrically connected.

For example, the external device may be a charger or a load such as a motor of an electric vehicle that is powered by the battery 11.

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### EXPLANATION OF REFERENCE SIGNS

10: battery pack
11: battery
12: measuring unit
100: battery information generating apparatus
110: profile obtaining unit
120: voltage comparing unit
130: measurement value determining unit
140: diagnostic resistance determining unit
150: storage unit

What is claimed is:

1. A battery information generating method, comprising:
obtaining a differential profile representing a corresponding relationship between a voltage and a differential capacity of a battery;
detecting a peak in the differential profile;
comparing a peak voltage corresponding to the peak with a preset reference voltage;
determining a measurement resistance of the battery by determining a resistance during discharging of the battery for a predetermined time from a discharge start point; and
determining a diagnostic resistance of the battery based on the measurement resistance according to a comparison result of comparing the peak voltage corresponding to the peak with the present reference voltage.

2. The battery information generating method according to claim 1,
wherein determining the diagnostic resistance includes determining the measurement resistance as the diagnostic resistance when the peak voltage is less than the reference voltage.

3. The battery information generating method according to claim 1,
wherein determining the measurement resistance further includes determining the voltage of the discharge start point as a measurement voltage when the peak voltage is greater than or equal to the reference voltage.

4. The battery information generating method according to claim 3,
wherein determining the diagnostic resistance includes:
correcting the measurement resistance based on the measurement voltage, the peak voltage and a preset resistance profile; and
determining the corrected measurement resistance as the diagnostic resistance,
wherein the resistance profile is a profile that is preset to correspond to the battery and represents a corresponding relationship between the voltage and a resistance.

5. The battery information generating method according to claim 4,
wherein determining the measurement resistance includes:
calculating a first value based on the measurement voltage and a target voltage;
calculating a second value based on the target voltage and the resistance profile;
calculating a third value based on the first value and the second value; and
calculating the corrected measurement resistance based on the third value and the measurement resistance,
wherein the target voltage is determined as a voltage that is greater than or equal to the reference voltage among the peak voltages.

6. The battery information generating method according to claim 5,
wherein the first value corresponds to a difference between the measurement voltage and the target voltage.

7. The battery information generating method according to claim 5,
wherein the second value corresponds to a rate of change of the resistance for the voltage in a target voltage section of the resistance profile, and
wherein the target voltage section is a voltage section that is greater than or equal to the target voltage.

8. The battery information generating method according to claim 5,
wherein the third value is a value that is obtained by multiplying the first value by the second value.

9. The battery information generating method according to claim 5,
wherein the corrected measurement resistance is a value that is obtained by adding the third value to the measurement resistance.

10. A battery information generating apparatus, comprising:
a profile obtaining unit configured to obtain a differential profile representing a corresponding relationship between a voltage and a differential capacity of a battery;
a voltage comparing unit configured to detect a peak in the differential profile and compare a peak voltage corresponding to the peak with a preset reference voltage;
a measurement value determining unit configured to determine a measurement resistance of the battery by determining a resistance during discharging of the battery for a predetermined time from a discharge start point; and
a diagnostic resistance determining unit configured to determine a diagnostic resistance of the battery based on the measurement resistance according to a comparison result of comparing the peak voltage corresponding to the peak with the preset reference voltage.

11. The battery information generating apparatus according to claim 10,
wherein the diagnostic resistance determining unit is configured to determine the measurement resistance as the diagnostic resistance when the peak voltage is less than the reference voltage.

12. The battery information generating apparatus according to claim 10,
wherein the measurement value determining unit is configured to determine the voltage of the discharge start point as a measurement voltage when the peak voltage is greater than or equal to the reference voltage.

13. The battery information generating apparatus according to claim 12,
wherein the diagnostic resistance determining unit is configured to correct the measurement resistance based on the measurement voltage, the peak voltage and a preset resistance profile, and determine the corrected measurement resistance as the diagnostic resistance, and
wherein the resistance profile is a profile that is preset to correspond to the battery and represents a corresponding relationship between the voltage and a resistance.

14. The battery information generating apparatus according to claim 13,
wherein the diagnostic resistance determining unit is configured to calculate a first value based on the measurement voltage and a target voltage, calculate a second value based on the target voltage and the resistance profile; calculate a third value based on the first value and the second value, and calculate the corrected measurement resistance based on the third value and the measurement resistance, and
wherein the target voltage is determined as a voltage that is greater than or equal to the reference voltage among the peak voltages.

15. The battery information generating apparatus according to claim 14,
wherein the first value corresponds to a difference between the measurement voltage and the target voltage.

16. The battery information generating apparatus according to claim 14,
wherein the second value corresponds to a rate of change of the resistance for the voltage in a target voltage section of the resistance profile, and
wherein the target voltage section is a voltage section that is greater than or equal to the target voltage.

17. The battery information generating apparatus according to claim 14,
wherein the third value is a value that is obtained by multiplying the first value by the second value.

18. The battery information generating apparatus according to claim 14,
wherein the corrected measurement resistance is a value that is obtained by adding the third value to the measurement resistance.

19. A battery management system, comprising the battery information generating apparatus according to claim 10.

20. A battery pack, comprising the battery information generating apparatus according to claim 10.
